(19) United States
(12) Patent Application Publication
(10) Pub. No.: US 2024/0224584 A1
(43) Pub. Date: Jul. 4, 2024

(54) DISPLAY DEVICE AND DISPLAY PANEL THEREOF, AND OLED DISPLAY DEVICE

(71) Applicant: BOE Technology Group Co., Ltd., Beijing (CN)

(72) Inventors: Hao GAO, Beijing (CN); Yan FAN, Beijing (CN); Xing FAN, Beijing (CN); Xu LI, Beijing (CN); Zhihui ZHANG, Beijing (CN); Xiangmin WEN, Beijing (CN)

(21) Appl. No.: 17/914,155

(22) PCT Filed: Oct. 26, 2021
(86) PCT No.: PCT/CN2021/126490

§ 371 Date: Sep. 23, 2022

(30) Foreign Application Priority Data
Mar. 31, 2021 (CN) 202110352185.2

(51) Int. Cl. H10K 50/858; H10K 50/15; H10K 50/16; H10K 50/18; H10K 102/00

(52) U.S. Cl. CPC H10K 50/858; H10K 50/15; H10K 50/16; H10K 50/181; H10K 2102/3026

(57) ABSTRACT

A display device and a display panel thereof, and an OLED display device are provided. The OLED display device includes: a red light-emitting structure, a green light-emitting structure, and a blue light-emitting structure, where (n_{3z}-n_{3xy})-(n_{1z}-n_{1xy})≥a first preset value, and (n_{3z}-n_{3xy})-(n_{2z}-n_{2xy})≥a second preset value, where ranges of both the first preset value and the second preset value are 0.1˜0.3; n_{1z} is a sum of refractive indexes of respective layers of the red light-emitting structure in a thickness direction; n_{1xy} is a sum of refractive indexes of the respective layers of the red light-emitting structure in a vertical thickness direction; n_{2z} is a sum of refractive indexes of respective layers of the green light-emitting structure in the thickness direction; n_{2xy} is a sum of refractive indexes of the respective layers of the green light-emitting structure in the vertical thickness direction; n_{3z} is a sum of refractive indexes of respective layers of the blue light-emitting structure in the thickness direction; and n3xy is a sum of refractive indexes of the respective layers of the blue light-emitting structure in the vertical thickness direction. According to embodiments of the present disclosure, a reflectance of an interface between the blue light-emitting structure and outside at a large angle of view can be reduced, a light transmittance can be increased, a brightness can be enhanced, and further a color shift can be improved.

### CROSS REFERENCE TO RELATED APPLICATIONS

The present application is a U.S. national phase of PCT Application No. PCT/CN2021/126490, filed on Oct. 26, 2021, which claims priority to Chinese Patent Application No. 202110352185.2, filed on Mar. 31, 2021, the entire contents of which are incorporated herein by reference for all purposes.

### TECHNICAL FIELD

The present application relates to the field of display device technologies, and in particular, to a display device and a display panel thereof, and an OLED display device.

### BACKGROUND

Compared with currently widely applied liquid crystal and plasma displays, Organic Light-Emitting Diode (OLED) devices have attracted much attention due to their advantages such as self-luminescence, rich colors, fast response speed, wide angle of view, light weight, thin thickness, low power consumption, and flexible display.

However, in the related art, when an OLED screen is viewed at different angles of view, for example, at a large angle of view, a color of the screen changes greatly, that is, there is a serious color shift problem. For example, there appears white light at an angle of front view, but there may tend to be yellowish at an angle of view of 80 degrees.

A color shift of OLED products at an angle of view is one of important evaluation indicators. Due to consideration of life service, efficiency, color gamut, and various factors of existing products, it is difficult to improve a color shift problem at a large angle of view.

### SUMMARY

The present disclosure provides a display device and a display panel thereof, and an OLED display device to solve deficiencies in the related art.

In order to achieve the above object, according to a first aspect of the present disclosure, there is provided an OLED display device, including: a red light-emitting structure, a green light-emitting structure, and a blue light-emitting structure, where (n_{3z}-n_{3xy})-(n_{1z}-n_{1xy})≥a first preset value, and (n_{3z}-n_{3xy})-(n_{2z}-n_{2xy})≥a second preset value, where ranges of both the first preset value and the second preset value are 0.1˜0.3; n_{1z} is a sum of refractive indexes of respective layers of the red light-emitting structure in a thickness direction; n_{1xy} is a sum of refractive indexes of the respective layers of the red light-emitting structure in a vertical thickness direction; n_{2z} is a sum of refractive indexes of respective layers of the green light-emitting structure in the thickness direction; n_{2xy} is a sum of refractive indexes of the respective layers of the green light-emitting structure in the vertical thickness direction; n_{3z} is a sum of refractive indexes of respective layers of the blue light-emitting structure in the thickness direction; and n_{3xy} is a sum of refractive indexes of the respective layers of the blue light-emitting structure in the vertical thickness direction.

In some examples, the respective layers of the red light-emitting structure include a first anode, a first cathode, and a red OLED light-emitting block located between the first anode and the first cathode; the respective layers of the green light-emitting structure include a second anode, a second cathode, and a green OLED light-emitting block located between the second anode and the second cathode; the respective layers of the blue light-emitting structure include a third anode, a third cathode, and a blue OLED light-emitting block located between the third anode and the third cathode.

In some examples, the first anode, the second anode, and the third anode are located in a same layer and any two among them are disconnected to each other, and the first cathode, the second cathode, and the third cathode are located in a same layer and are connected together;
(n_{31z}-n_{31xy})-(n_{11z}-n_{11xy})≥the first preset value, and (n_{31z}-n_{31xy})-(n_{21z}-n_{21xy})≥the second preset value, where n_{11z} is a refractive index of the first anode in the thickness direction; n_{11xy} is a refractive index of the first anode in the vertical thickness direction; n_{21z} is a refractive index of the second anode in the thickness direction; n_{21xy} is a refractive index of the second anode in the vertical thickness direction; n_{31z} is a refractive index of the third anode in the thickness direction; n_{31xy} is a refractive index of the third anode in the vertical thickness direction; and/or
(n_{32z}-n_{32xy})-(n_{12z}-n_{12xy})≥the first preset value, and (n_{32z}-n_{32xy})-(n_{22z}-n_{22xy})≥the second preset value, where n_{12z} is a refractive index of the red OLED light-emitting block in the thickness direction; n_{12xy} is a refractive index of the red OLED light-emitting block in the vertical thickness direction; n_{22z} is a refractive index of the green OLED light-emitting block in the thickness direction; n_{22xy} is a refractive index of the green OLED light-emitting block in the vertical thickness direction; n_{32z} is a refractive index of the blue OLED light-emitting block in the thickness direction; n_{32xy} is a refractive index of the blue OLED light-emitting block in the vertical thickness direction.

In some examples, the respective layers of the red light-emitting structure further include at least one of a first hole transport layer, a first electron barrier layer, a first hole barrier layer, or a first electron transport layer, where the first hole transport layer and the first electron barrier layer are located between the first anode and the red OLED light-emitting block, the first hole transport layer is close to the first anode, the first electron barrier layer is far away from the first anode, the first hole barrier layer and the first electron transport layer are located between the first cathode and the red OLED light-emitting block, the first hole barrier layer is far away from the first cathode, and the first electron transport layer is close to the first cathode;
the respective layers of the green light-emitting structure further include at least one of a second hole transport layer, a second electron barrier layer, a second hole barrier layer, or a second electron transport layer, where the second hole transport layer and the second electron barrier layer are located between the second anode and the green OLED light-emitting block, the second hole transport layer is close to the second anode, the second electron barrier layer is far away from the second anode, the second hole barrier layer and the second electron transport layer are located between the second cathode and the green OLED light-emitting block, the second hole barrier layer is far away from the second cathode, and the second electron transport layer is close to the second cathode;
the respective layers of the blue light-emitting structure further include at least one of a third hole transport layer, a third electron barrier layer, a third hole barrier layer, or a third electron transport layer, where the third hole transport layer and the third electron barrier layer are located between the third anode and the blue OLED light-emitting block, the third hole transport layer is close to the third anode, the third electron barrier layer is far away from the third anode, the third hole barrier layer and the third electron transport layer are located between the third cathode and the blue OLED light-emitting block, the third hole barrier layer is far away from the third cathode, and the third electron transport layer is close to the third cathode.

In some examples, the first hole transport layer, the second hole transport layer, and the third hole transport layer are located in a same layer and any two among them are disconnected to each other; (n_{33z}-n_{33xy})-(n_{13z}-n_{13xy})≥the first preset value, and (n_{33z}-n_{33xy})-(n_{23z}-n_{23xy})≥the second preset value, where n_{13z} is a refractive index of the first hole transport layer in the thickness direction, n_{13xy} is a refractive index of the first hole transport layer in the vertical thickness direction, n_{23z} is a refractive index of the second hole transport layer in the thickness direction, n_{23xy} is a refractive index of the second hole transport layer in the vertical thickness direction, n_{33z} is a refractive index of the third hole transport layer in the thickness direction, and n_{33xy} is a refractive index of the third hole transport layer in the vertical thickness direction; and/or
the first electron barrier layer, the second electron barrier layer, and the third electron barrier layer are located in a same layer and any two among them are disconnected to each other; (n_{34z}-n_{34xy})-(n_{14z}-n_{14xy})≥the first preset value, and (n_{34z}-n_{34xy})-(n_{24z}-n_{24xy})≥the second preset value, where n_{14z} is a refractive index of the first electron barrier layer in the thickness direction, n_{14xy} is a refractive index of the first electron barrier layer in the vertical thickness direction, n_{24z} is a refractive index of the second electron barrier layer in the thickness direction, n_{24xy} is a refractive index of the second electron barrier layer in the vertical thickness direction, n_{34z} is a refractive index of the third electron barrier layer in the thickness direction, and n_{34xy} is a refractive index of the third electron barrier layer in the vertical thickness direction; and/or
the first hole barrier layer, the second hole barrier layer, and the third hole barrier layer are located in a same layer and any two among them are disconnected to each other; (n_{35z}-n_{35xy})-(n_{15z}-n_{15xy})≥the first preset value, and (n_{35z}-n_{35xy})-(n_{25z}-n_{25xy})≥the second preset value, where n_{15z} is a refractive index of the first hole barrier layer in the thickness direction, n_{15xy} is a refractive index of the first hole barrier layer in the vertical thickness direction, n_{25z} is a refractive index of the second hole barrier layer in the thickness direction, n_{25xy} is a refractive index of the second hole barrier layer in the vertical thickness direction, n_{35z} is a refractive index of the third hole barrier layer in the thickness direction, and n_{35xy} is a refractive index of the third hole barrier layer in the vertical thickness direction; and/or
the first electron transport layer, the second electron transport layer, and the third electron transport layer are located in a same layer and any two among them are disconnected to each other; (n_{36z}-n_{36xy})-(n_{16z}-n_{16xy})≥the first preset value, and (n_{36z}-n_{36xy})-(n_{26z}-n_{26xy})≥the second preset value, where n_{16z} is a refractive index of the first electron transport layer in the thickness direction, n_{16xy} is a refractive index of the first electron transport layer in the vertical thickness direction, n_{26z} is a refractive index of the second electron transport layer in the thickness direction, n_{26xy} is a refractive index of the second electron transport layer in the vertical thickness direction, n_{36z} is a refractive index of the third electron transport layer in the thickness direction, and n_{36xy} is a refractive index of the third electron transport layer in the vertical thickness direction.

In some examples, the respective layers of the red light-emitting structure further include a first light extraction layer, where the first light extraction layer is located on a side of the first cathode away from the red OLED light-emitting block; the respective layers of the green light-emitting structure further include a second light extraction layer, where the second light extraction layer is located on a side of the second cathode away from the green OLED light-emitting block; the respective layers of the blue light-emitting structure further include a third light extraction layer, where the third light extraction layer is located on a side of the third cathode away from the blue OLED light-emitting block.

In some examples, the first light extraction layer, the second light extraction layer, and the third light extraction layer are located in a same layer and any two among them are disconnected to each other; (n_{37z}-n_{37xy})-(n_{17z}-n_{17xy})≥the first preset value, and (n_{37z}-n_{37xy})-(n_{27z}-n_{27xy})≥the second preset value, where n_{17z} is a refractive index of the first light extraction layer in the thickness direction, n_{17xy} is a refractive index of the first light extraction layer in the vertical thickness direction, n_{27z} is a refractive index of the second light extraction layer in the thickness direction, n_{27xy} is a refractive index of the second light extraction layer in the vertical thickness direction, n_{37z} is a refractive index of the third light extraction layer in the thickness direction, and n_{37xy} is a refractive index of the third light extraction layer in the vertical thickness direction.

In some examples, n_{1z}=n_{1xy}, and/or n_{2z}=n_{2xy}.

In some examples, n_{3z}-n_{3xy}≥a third preset value, and n_{1z}-n_{1xy}≤a fourth preset value, where the third preset value−the fourth preset value=the first preset value; n_{2z}-n_{2xy}≤a fifth preset value, where the third preset value−the fifth preset value=the second preset value.

In some examples, n₁ₓ=n_{1y}, and/or n₂ₓ=n_{2y}, and/or n₃ₓ=n_{3y}, where n₁ₓ is a sum of refractive indexes of the respective layers of the red light-emitting structure in a first direction in a plane where the vertical thickness direction is located, n_{1y} is a sum of refractive indexes of the respective layers of the red light-emitting structure in a second direction in the plane where the vertical thickness direction is located, n₂ₓ is a sum of refractive indexes of the respective layers of the green light-emitting structure in the first direction in the plane where the vertical thickness direction is located, n_{2y} is a sum of refractive indexes of the respective layers of the green light-emitting structure in the second direction in the plane where the vertical thickness direction is located, n₃ₓ is a sum of refractive indexes of the respective layers of the blue light-emitting structure in the first direction in the plane where the vertical thickness direction is located, n_{3y} is a sum of refractive indexes of the respective layers of the blue light-emitting structure in the second direction in the plane where the vertical thickness direction is located, where the first direction is perpendicular to the second direction.

In some examples, (n₃ₓ-n_{3y})-(n₁ₓ-n_{1y})≥a sixth preset value, and (n₃ₓ-n_{3y})-(n₂ₓ-n_{2y})≥a seventh preset value, where ranges of both the sixth preset value and the seventh preset value are 0.1˜0.3, n₁ₓ is a sum of refractive indexes of the respective layers of the red light-emitting structure in a first direction in a plane where the vertical thickness direction is located, n_{1y} is a sum of refractive indexes of the respective layers of the red light-emitting structure in a second direction in the plane where the vertical thickness direction is located, n₂ₓ is a sum of refractive indexes of the respective layers of the green light-emitting structure in the first direction in the plane where the vertical thickness direction is located, n_{2y} is a sum of refractive indexes of the respective layers of the green light-emitting structure in the second direction in the plane where the vertical thickness direction is located, n₃ₓ is a sum of refractive indexes of the respective layers of the blue light-emitting structure in the first direction in the plane where the vertical thickness direction is located, n_{3y} is a sum of refractive indexes of the respective layers of the blue light-emitting structure in the second direction in the plane where the vertical thickness direction is located, where the first direction is perpendicular to the second direction.

In some examples, (n_{3y}-n₃ₓ)-(n_{1y}-n₁ₓ)≥a sixth preset value, and (n_{3y}-n₃ₓ)-(n_{2y}-n₂ₓ)≥a seventh preset value, where ranges of both the sixth preset value and the seventh preset value are 0.1˜0.3, n₁ₓ is a sum of refractive indexes of the respective layers of the red light-emitting structure in a first direction in a plane where the vertical thickness direction is located, n_{1y} is a sum of refractive indexes of the respective layers of the red light-emitting structure in a second direction in the plane where the vertical thickness direction is located, n₂ₓ is a sum of refractive indexes of the respective layers of the green light-emitting structure in the first direction in the plane where the vertical thickness direction is located, n_{2y} is a sum of refractive indexes of the respective layers of the green light-emitting structure in the second direction in the plane where the vertical thickness direction is located, n₃ₓ is a sum of refractive indexes of the respective layers of the blue light-emitting structure in the first direction in the plane where the vertical thickness direction is located, n_{3y} is a sum of refractive indexes of the respective layers of the blue light-emitting structure in the second direction in the plane where the vertical thickness direction is located, where the first direction is perpendicular to the second direction.

According to a second aspect of the present disclosure, there is provided a display panel, including: OLED display devices as described above, where the OLED display devices are arranged in an array.

In some examples, the OLED display devices have a bottom or top emission structure.

According to a third aspect of the present disclosure, there is provided a display device, including: a display panel as described above.

Inventors analyzed the color shift problem in the related art, and found its reason is that a brightness of the blue light-emitting structure attenuates faster than that of the red light-emitting structure and the green light-emitting structure as an angle of view increases.

Based on the above analysis, in the embodiments of the present disclosure, by controlling an anisotropic refractive index of the respective layers of the red light-emitting structure, the green light-emitting structure, and the blue light-emitting structure in the thickness direction and the vertical thickness direction, (n_{3z}-n_{3xy})-(n_{1z}-n_{1xy})≥the first preset value, and (n_{3z}-n_{3xy})-(n_{2z}-n_{2xy})≥the second preset value, where ranges of both the first preset value and the second preset value are 0.1˜0.3; n_{1z} is the sum of the refractive indexes of the respective layers of the red light-emitting structure in the thickness direction; n_{1xy} is the sum of the refractive indexes of the respective layers of the red light-emitting structure in the vertical thickness direction; n_{2z} is the sum of the refractive indexes of the respective layers of the green light-emitting structure in the thickness direction; n_{2xy} is the sum of the refractive indexes of the respective layers of the green light-emitting structure in the vertical thickness direction; n_{3z} is the sum of the refractive indexes of the respective layers of the blue light-emitting structure in the thickness direction; and n3xy is the sum of the refractive indexes of the respective layers of the blue light-emitting structure in the vertical thickness direction. Therefore, a reflectance of an interface between the blue light-emitting structure and outside at a large angle of view can be reduced, a light transmittance can be increased, a brightness can be enhanced, and further a color shift can be improved.

It should be understood that the above general description and the following detailed description are only exemplary and explanatory and are not restrictive of the present disclosure.

### BRIEF DESCRIPTION OF THE DRAWINGS

The accompanying drawings, which are incorporated in and constitute a part of this specification, illustrate examples consistent with the present disclosure and, together with the description, serve to explain the principles of the present disclosure.

FIG. 1 is a top view of an OLED display device according to a first embodiment of the present disclosure.

FIG. 2 is a cross-sectional view taken along a line AA in FIG. 1.

FIG. 3 is a graph illustrating changes in a color shift of a blue light-emitting structure in the related art and a blue light-emitting structure according to this embodiment as an angle of view deviates from front view in an X direction under a condition of emitting white light in the front view in a horizontal direction.

FIG. 4 is a graph illustrating changes in a ratio of an actual brightness to a required brightness of the blue light-emitting structure in the related art and the blue light-emitting structure according to this embodiment as an angle of view deviates from front view in an X direction.

FIG. 5 is a schematic diagram illustrating a cross-sectional structure of an OLED display device according to a second embodiment of the present disclosure.

FIG. 6 is a schematic diagram illustrating a cross-sectional structure of an OLED display device according to a third embodiment of the present disclosure.

List of reference numerals:

| | |
|---|---|
| OLED display devices 1, 2, 3 | Substrate 10 |
| Red light-emitting structure 11 | Green light-emitting structure 12 |
| Blue light-emitting structure 13 | First anode 111 |
| First cathode 112 | Red OLED light-emitting block 113 |
| Second anode 121 | Second cathode 122 |
| Green OLED light-emitting | Third anode 131 |
| block 123 | |
| Third cathode 132 | Blue OLED light-emitting block 133 |
| First hole transport layer HTL1 | First electron barrier layer EBL1 |
| First hole barrier layer HBL1 | First electron transport layer ETL1 |
| Second hole transport layer HTL2 | Second electron barrier layer EBL2 |
| Second hole barrier layer HBL2 | Second electron transport layer ETL2 |
| Third hole transport layer HTL3 | Third electron barrier layer EBL3 |
| Third hole barrier layer HBL3 | Third electron transport layer ETL3 |
| First light extraction layer CPL1 | Second light extraction layer CPL2 |
| Third light extraction layer CPL3 | |

### DETAILED DESCRIPTION OF THE EMBODIMENTS

Examples will be described in detail herein, with the illustrations thereof represented in the drawings. When the following descriptions involve the drawings, like numerals in different drawings refer to like or similar elements unless otherwise indicated. The embodiments described in the following examples do not represent all embodiments consistent with the present disclosure. Rather, they are merely examples of apparatuses and methods consistent with some aspects of the present disclosure as detailed in the appended claims.

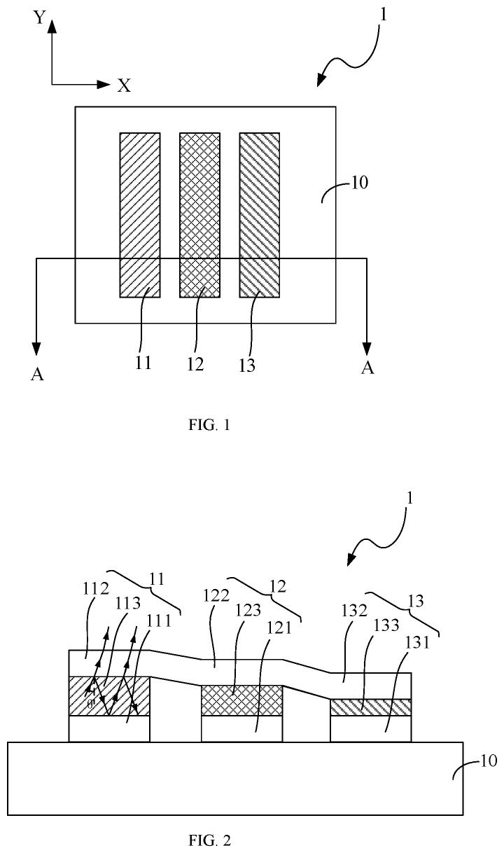

FIG. 1 is a top view of an OLED display device according to a first embodiment of the present disclosure. FIG. 2 is a cross-sectional view taken along a line AA in FIG. 1.

Referring to FIG. 1 and FIG. 2, an OLED display device 1 includes: a red light-emitting structure 11, a green light-emitting structure 12, and a blue light-emitting structure 13. (n_{3z}-n_{3xy})-(n_{1z}-n_{1xy})≥a first preset value, and (n_{3z}-n_{3xy})-(n_{2z}-n_{2xy})≥a second preset value, where ranges of both the first preset value and the second preset value are 0.1˜0.3; n_{1z} is a sum of refractive indexes of respective layers of the red light-emitting structure 11 in a thickness direction; n_{1xy} is a sum of refractive indexes of respective layers of the red light-emitting structure 11 in a vertical thickness direction; n_{2z} is a sum of refractive indexes of respective layers of the green light-emitting structure 12 in the thickness direction; n_{2xy} is a sum of refractive indexes of respective layers of the green light-emitting structure 12 in the vertical thickness direction; n_{3z} is a sum of refractive indexes of respective layers of the blue light-emitting structure 13 in the thickness direction; and n_{3xy} is a sum of refractive indexes of respective layers of the blue light-emitting structure 13 in the vertical thickness direction.

Referring to FIG. 2, the OLED display device 1 can be disposed on a substrate 10. The substrate 10 may be a flexible substrate or a rigid substrate. Materials for the flexible substrate may be polyimide, and materials for the rigid substrate may be glass.

In this embodiment, referring to FIG. 2, the red light-emitting structure 11 may include a first anode 111, a first cathode 112, and a red OLED light-emitting block 113 located between the first anode 111 and the first cathode 112.

The green light-emitting structure 12 may include a second anode 121, a second cathode 122, and a green OLED light-emitting block 123 located between the second anode 121 and the second cathode 122.

The blue light-emitting structure 13 may include a third anode 131, a third cathode 132, and a blue OLED light-emitting block 133 located between the third anode 131 and the third cathode 132.

In this embodiment, the first anode 111, the second anode 121 and the third anode 131 are close to the substrate 10, and the first cathode 112, the second cathode 122 and the third cathode 132 are far away from the substrate 10. A pixel definition layer (not shown) may be disposed on the first anode 111, the second anode 121, the third anode 131, and the substrate 10 on which no first anode 111, second anode 121 and third anode 131 are disposed. The pixel definition layer has a plurality of openings, and the openings correspond to partial regions exposing the first anode 111, the second anode 121, and the third anode 131. The red OLED light-emitting block 113, the green OLED light-emitting block 123, and the blue OLED light-emitting block 133 are respectively located in corresponding openings. The first cathode 112, the second cathode 122, and the third cathode 132 are correspondingly located on the red OLED light-emitting block 113, the green OLED light-emitting block 123, the blue OLED light-emitting block 133, and the pixel definition layer.

Referring to FIG. 2, in this embodiment, the red light-emitting structure 11, the green light-emitting structure 12, and the blue light-emitting structure 13 each form a Fabry-Perot resonant cavity.

According to the principle of the Fabry-Perot resonant cavity, the resonant cavity is formed by enabling two parallel polar plates with a high reflectance to face each other, and when a frequency of incident light in the resonant cavity satisfies resonance conditions of the resonant cavity, a transmission spectrum will have a high peak, which corresponds to a high transmittance, so that the resonant cavity with predetermined characteristics can allow light with a corresponding wavelength to transmit there-through. Therefore, there is a correspodence between a cavity length of the Fabry-Perot resonant cavity and the wavelength of light, and microcavity structures with different cavity lengths can allow light only with a specific wavelength to transmit there-through.

When light is reflected back and forth in the Fabry-Perot resonant cavity, the light is also transmitted and reflected on interfaces of adjacent layers in the cavity. In addition, the light will be transmitted and reflected on an emergent light interface of the resonant cavity.

An interface reflectance

$$R = {( \frac{N 1 * COS θ - \sqrt{N {2}^{2} - N {1}^{2} {SIN}^{2} θ}}{N 1 * COS θ + \sqrt{N {2}^{2} - N {1}^{2} {SIN}^{2} θ}} )}^{2} ,$$

where N1 and N2 are refractive indexes of media on both sides of an interface respectively, and θ is a reflection angle.

In an example, when the red light-emitting structure 11, the green light-emitting structure 12, and the blue light-emitting structure 13 are in front view, θ is 0 degree, N132 N1z, and N2=N2z, where N1z and N2z are refractive indexes of media on both sides of an interface in the thickness direction respectively.

When an angle of view is large, in the red light-emitting structure 11, the green light-emitting structure 12, and a blue light-emitting structure in the related art, N1≈N1xy=N1z, and N2≈N2xy=N2z; in the blue light-emitting structure 13 according to this embodiment, N1xy=N1z, and N2≈N2xy<N2z, where N1xy and N2xy are refractive indexes of media on both sides of an interface in the vertical thickness direction respectively. In this embodiment, refractive indexes of media in the vertical thickness direction refer to refractive indexes of media in any direction in a plane where the vertical thickness direction is located.

In other words, respective layers in the red light-emitting structure 11, the green light-emitting structure 12, and the blue light-emitting structure in the related art have an isotropic refractive index in the thickness direction and the vertical thickness direction. Respective layers of the blue light-emitting structure 13 according to this embodiment have an anisotropic refractive index in the thickness direction and the vertical thickness direction.

For a same large angle of view θ, a reflectance R1 of the red light-emitting structure 11, the green light-emitting structure 12 and the blue light-emitting structure in the related art on an interface is:

$$R 1 = {( \frac{N 1 xy * COS θ - \sqrt{N 2 {xy}^{2} - N 1 {xy}^{2} {SIN}^{2} θ}}{N 1 xy * COS θ + \sqrt{N 2 {xy}^{2} - N 1 {xy}^{2} {SIN}^{2} θ}} )}^{2} = {( \frac{N 1 xy * COS θ - \sqrt{N 2 {z}^{2} - N 1 {xy}^{2} {SIN}^{2} θ}}{N 1 xy * COS θ + \sqrt{N 2 {z}^{2} - N 1 {xy}^{2} {SIN}^{2} θ}} )}^{2} ;$$

A reflectance R2 of the blue light-emitting structure 13 according to this embodiment on an interface is:

$$R 2 = {( \frac{N 1 xy * COS θ - \sqrt{N 2 {xy}^{2} - N 1 {xy}^{2} {SIN}^{2} θ}}{N 1 xy * COS θ + \sqrt{N 2 {xy}^{2} - N 1 {xy}^{2} {SIN}^{2} θ}} )}^{2} .$$

It can be seen that N2xy<N2z will lead to R2<R1.

In order to verify the above conclusion, when an angle of view is large, in the red light-emitting structure 11, the green light-emitting structure 12, and the blue light-emitting structure in the related art, N1≈N1xy=N1z=1 (corresponding to a refractive index of outside air), and N2≈N2xy=N2z=1.8; in the blue light-emitting structure 13 according to this embodiment, N1≈N1xy=N1z=1 (corresponding to a refractive index of outside air), and N2≈N2xy=1.7. R2<R1 can be obtained.

R2<R1 will cause a light transmittance of the blue light-emitting structure 13 according to this embodiment to be greater than that of the red light-emitting structure 11, the green light-emitting structure 12, and the blue light-emitting structure in the related art, thereby increasing a brightness of the blue light-emitting structure 13 according to this embodiment at a large angle of view, and further improving a color shift.

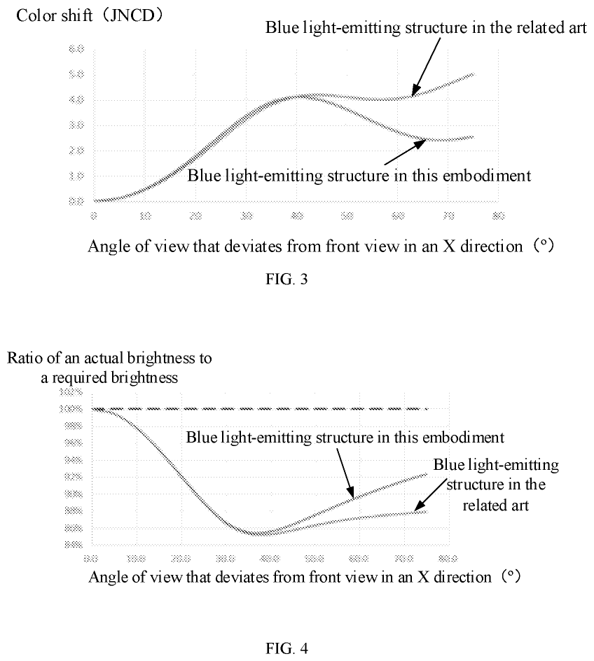

In order to verify the above beneficial effect, FIG. 3 is a graph illustrating changes in a color shift of the blue light-emitting structure in the related art and the blue light-emitting structure 13 according to this embodiment as an angle of view deviates from front view in an X direction under a condition of emitting white light in the front view in a horizontal direction. FIG. 4 is a graph illustrating changes in a ratio of an actual brightness to a required brightness of the blue light-emitting structure in the related art and the blue light-emitting structure 13 according to this embodiment as an angle of view deviates from front view in an X direction.

Referring to FIG. 3, at a large angle of view, a color shift of the blue light-emitting structure 13 according to this embodiment is smaller than that of the blue light-emitting structure in the related art.

Referring to FIG. 4, at a large angle of view, a ratio of an actual brightness to a required brightness of the blue light-emitting structure 13 according to this embodiment is greater than that of the blue light-emitting structure in the related art.

First, the red light-emitting structure 11, the green light-emitting structure 12, and the blue light-emitting structure 13, which constitute the resonant cavity, respectively have multiple layers, that is, multiple interfaces. Second, the color shift has relativity among the red light-emitting structure 11, the green light-emitting structure 12, and the blue light-emitting structure 13. Third, luminous efficiency distribution of the red light-emitting structure 11, the green light-emitting structure 12, and the blue light-emitting structure 13 in both front view and a large angle of view is taken into consideration. Considering the three factors, refractive indexes of respective layers of the red light-emitting structure 11, the green light-emitting structure 12, and the blue light-emitting structure 13 in the thickness direction and the vertical thickness direction are set as: (n_{3z}-n_{3xy})-(n_{1z}-n_{1xy})≥a first preset value, and (n_{3z}-n_{3xy})-(n_{2z}-n_{2xy})≥a second preset value, where ranges of both the first preset value and the second preset value are 0.1˜0.3; n_{1z} is a sum of refractive indexes of respective layers of the red light-emitting structure 11 in the thickness direction; n_{1xy} is a sum of refractive indexes of respective layers of the red light-emitting structure 11 in the vertical thickness direction; n_{2z} is a sum of refractive indexes of respective layers of the green light-emitting structure 12 in the thickness direction; n_{2xy} is a sum of refractive indexes of respective layers of the green light-emitting structure 12 in the vertical thickness direction; n_{3z} is a sum of refractive indexes of respective layers of the blue light-emitting structure 13 in the thickness direction; and n_{3xy} is a sum of refractive indexes of respective layers of the blue light-emitting structure 13 in the vertical thickness direction.

The numerical range in this embodiment includes endpoint values.

In some examples, n_{1z}=n_{1xy}, and/or n_{2z}=n_{2xy}. Correspondingly, n_{3z}-n_{3xy}≥a first preset value, and/or n_{3z}-n_{3xy}≥a second preset value.

In other examples, n_{3z}-n_{3xy}≥a third preset value, and n_{1z}-n_{1xy}≤a fourth preset value, where the third preset value−the fourth preset value=the first preset value; n_{2z}-n_{2xy}≤a fifth preset value, where the third preset value−the fifth preset value=the second preset value.

In addition, in this embodiment, n₁ₓ=n_{1y}, and/or n₂ₓ=n_{2y}, and/or n₃ₓ=n_{3y}.

In this embodiment, referring to FIG. 2, the first anode 111, the second anode 121, and the third anode 131 are located in a same layer and any two among them are disconnected to each other, and the first cathode 112, the second cathode 122, and the third cathode 132 are located in a same layer and are connected together;
(n_{31z}-n_{31xy})-(n_{11z}-n_{11xy})≥a first preset value, and (n_{31z}-n_{31xy})-(n_{21z}-n_{21xy})≥a second preset value, where n_{11z} is a refractive index of the first anode 111 in the thickness direction; n_{11xy} is a refractive index of the first anode 111 in the vertical thickness direction; n_{21z} is a refractive index of the second anode 121 in the thickness direction; n_{21xy} is a refractive index of the second anode 121 in the vertical thickness direction; n_{31z} is a refractive index of the third anode 131 in the thickness direction; n_{31xy} is a refractive index of the third anode 131 in the vertical thickness direction; and/or
(n_{32z}-n_{32xy})-(n_{12z}-n_{12xy})≥a first preset value, and (n_{32z}-n_{32xy})-(n_{22z}-n_{22xy})≥a second preset value, where n_{12z} is a refractive index of the red OLED light-emitting block 113 in the thickness direction; n_{12xy} is a refractive index of the red OLED light-emitting block 113 in the vertical thickness direction; n_{22z} is a refractive index of the green OLED light-emitting block 123 in the thickness direction; n_{22xy} is a refractive index of the green OLED light-emitting block 123 in the vertical thickness direction; n_{32z} is a refractive index of the blue OLED light-emitting block 133 in the thickness direction; n_{32xy} is a refractive index of the blue OLED light-emitting block 133 in the vertical thickness direction.

The first anode 111, the second anode 121, and the third anode 131 as well as the red OLED light-emitting block 113, the green OLED light-emitting block 123, and the blue OLED light-emitting block 133 have an anisotropic refractive index in the thickness direction and the vertical thickness direction, which can be realized through material selection on one hand and process control on the other hand. For example, in a deposition process, temperatures of different regions on the substrate can be controlled to be different, so as to achieve that the first anode 111, the second anode 121, and the third anode 131 have an anisotropic refractive index in the thickness direction and the vertical thickness direction.

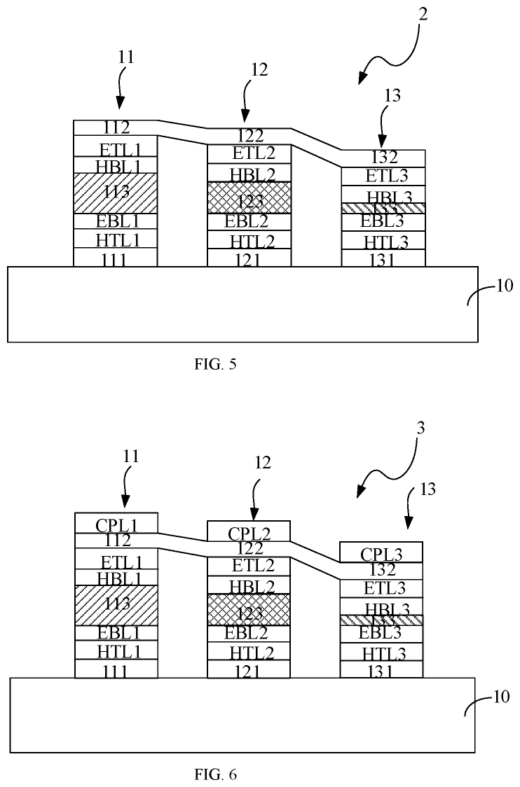

FIG. 5 is a schematic diagram illustrating a cross-sectional structure of an OLED display device according to a second embodiment of the present disclosure. Referring to FIG. 5, an OLED display device 2 according to this embodiment is substantially the same as the OLED display device 1 according to the first embodiment, except that: respective layers of the red light-emitting structure 11 further include at least one of a first hole transport layer HTL1, a first electron barrier layer EBL1, a first hole barrier layer HBL1, or a first electron transport layer ETL1, where the first hole transport layer HTL1 and the first electron barrier layer EBL1 are located between the first anode 111 and the red OLED light-emitting block 113, the first hole transport layer HTL1 is close to the first anode 111, the first electron barrier layer EBL1 is far away from the first anode 111, the first hole barrier layer HBL1 and the first electron transport layer ETL1 are located between the first cathode 112 and the red OLED light-emitting block 113, the first hole barrier layer HBL1 is far away from the first cathode 112, and the first electron transport layer ETL1 is close to the first cathode 112;
respective layers of the green light-emitting structure 12 further include at least one of a second hole transport layer HTL2, a second electron barrier layer EBL2, a second hole barrier layer HBL2, or a second electron transport layer ETL2, where the second hole transport layer HTL2 and the second electron barrier layer EBL2 are located between the second anode 121 and the green OLED light-emitting block 123, the second hole transport layer HTL2 is close to the second anode 121, the second electron barrier layer EBL2 is far away from the second anode 121, the second hole barrier layer HBL2 and the second electron transport layer ETL2 are located between the second cathode 122 and the green OLED light-emitting block 123, the second hole barrier layer HBL2 is far away from the second cathode 122, and the second electron transport layer ETL2 is close to the second cathode 122;
respective layers of the blue light-emitting structure 13 further include at least one of a third hole transport layer HTL3, a third electron barrier layer EBL3, a third hole barrier layer HBL3, or a third electron transport layer ETL3, where the third hole transport layer HTL3 and the third electron barrier layer EBL3 are located between the third anode 131 and the blue OLED light-emitting block 133, the third hole transport layer HTL3 is close to the third anode 131, the third electron barrier layer EBL3 is far away from the third anode 131. the third hole barrier layer HBL3 and the third electron transport layer ETL3 are located between the third cathode 132 and the blue OLED light-emitting block 133, the third hole barrier layer HBL3 is far away from the third cathode 132, and the third electron transport layer ETL is close to the third cathode 132.

The first hole transport layer HTL1, the second hole transport layer HTL2, and the third hole transport layer HTL3 are located in a same layer and any two among them are disconnected to each other; (n_{33z}-n_{33xy})-(n_{13z}-n_{13xy})≥a first preset value, and (n_{33z}-n_{33xy})-(n_{23z}-n_{23xy})≥a second preset value, where n_{13z} is a refractive index of the first hole transport layer HTL1 in the thickness direction, n_{13xy} is a refractive index of the first hole transport layer HTL1 in the vertical thickness direction, n_{23z} is a refractive index of the second hole transport layer HTL2 in the thickness direction, n_{23xy} is a refractive index of the second hole transport layer HTL2 in the vertical thickness direction, n_{33z} is a refractive index of the third hole transport layer HTL3 in the thickness direction, and n_{33xy} is a refractive index of the third hole transport layer HTL3 in the vertical thickness direction; and/or
the first electron barrier layer EBL1, the second electron barrier layer EBL2, and the third electron barrier layer EBL3 are located in a same layer and any two among them are disconnected to each other; (n_{34z}-n_{34xy})-(n_{14z}-n_{14xy})≥a first preset value, and (n_{34z}-n_{34xy})-(n_{24z}-n_{24xy})≥a second preset value, where n_{14z} is a refractive index of the first electron barrier layer EBL1 in the thickness direction, n_{14xy} is a refractive index of the first electron barrier layer EBL1 in the vertical thickness direction, n_{24z} is a refractive index of the second electron barrier layer EBL2 in the thickness direction, n_{24xy} is a refractive index of the second electron barrier layer EBL2 in the vertical thickness direction, n_{34z} is a refractive index of the third electron barrier layer EBL3 in the thickness direction, and n_{34xy} is a refractive index of the third electron barrier layer EBL3 in the vertical thickness direction; and/or
the first hole barrier layer HBL1, the second hole barrier layer HBL2, and the third hole barrier layer HBL3 are located in a same layer and any two among them are disconnected to each other; (n_{35z}-n_{35xy})-(n_{15z}-n_{15xy})≥a first preset value, and (n_{35z}-n_{35xy})-(n_{25z}-n_{25xy})≥a second preset value, where n_{15z} is a refractive index of the first hole barrier layer HBL1 in the thickness direction, n_{15xy} is a refractive index of the first hole barrier layer HBL1 in the vertical thickness direction, n_{25z} is a refractive index of the second hole barrier layer HBL2 in the thickness direction, n_{25xy} is a refractive index of the second hole barrier layer HBL2 in the vertical thickness direction, n_{35z} is a refractive index of the third hole barrier layer HBL3 in the thickness direction, and n_{35xy} is a refractive index of the third hole barrier layer HBL3 in the vertical thickness direction; and/or
the first electron transport layer ETL1, the second electron transport layer ETL2, and the third electron transport layer ETL3 are located in a same layer and any two among them are disconnected to each other; (n_{36z}-n_{36xy})-(n_{16z}-n_{16xy})≥a first preset value, and (n_{36z}-n_{36xy})-(n_{26z}-n_{26xy})≥a second preset value, where n_{16z} is a refractive index of the first electron transport layer ETL1 in the thickness direction, n_{16xy} is a refractive index of the first electron transport layer ETL1 in the vertical thickness direction, n_{26z} is a refractive index of the second electron transport layer ETL2 in the thickness direction, n_{26xy} is a refractive index of the second electron transport layer ETL2 in the vertical thickness direction, n_{36z} is a refractive index of the third electron transport layer ETL3 in the thickness direction, and n_{36xy} is a refractive index of the third electron transport layer ETL3 in the vertical thickness direction.

The anisotropic refractive index of the above respective layers in the thickness direction and the vertical thickness direction can be realized through material selection on one hand and process control on the other hand. For example, a refractive index of T2T in the thickness direction is 1.83, and a refractive index of T2T in the vertical thickness direction is 1.67. T2T can be selected as the third hole transport layer HTL3.

In this embodiment, an anisotropic refractive index of a film layer close to an OLED light-emitting block in the thickness direction and the vertical thickness direction is preferred.

In other embodiments, other film layers with an anisotropic refractive index can be disposed between the first anode 111 and the first cathode 112, and/or between the second anode 121 and the second cathode 122, and/or between the third anode 131 and the third cathode 132.

FIG. 6 is a schematic diagram illustrating a cross-sectional structure of an OLED display device according to a third embodiment of the present disclosure. Referring to FIG. 6, an OLED display device 3 according to this embodiment is substantially the same as the OLED display device 2 according to the second embodiment, except that:
respective layers of the red light-emitting structure 11 further include a first light extraction layer CPL1, where the first light extraction layer CPL1 is located on a side of the first cathode 112 away from the red OLED light-emitting block 113; respective layers of the green light-emitting structure 12 further include a second light extraction layer CPL2, where the second light extraction layer CPL2 is located on a side of the second cathode 122 away from the green OLED light-emitting block 123; respective layers of the blue light-emitting structure 13 further include a third light extraction layer CPL3, where the third light extraction layer CPL3 is located on a side of the third cathode 132 away from the blue OLED light-emitting block 133.

The first light extraction layer CPL1, the second light extraction layer CPL2, and the third light extraction layer CPL3 can be located in a same layer and any two among them are disconnected to each other; (n_{37z}-n_{37xy})-(n_{17z}-n_{17xy})≥a first preset value, and (n_{37z}-n_{37xy})-(n_{27z}-n_{27xy})≥a second preset value, where n_{17z} is a refractive index of the first light extraction layer CPL1 in the thickness direction, n_{17xy} is a refractive index of the first light extraction layer CPL1 in the vertical thickness direction, n_{27z} is a refractive index of the second light extraction layer CPL2 in the thickness direction, n_{27xy} is a refractive index of the second light extraction layer CPL2 in the vertical thickness direction, n_{37z} is a refractive index of the third light extraction layer CPL3 in the thickness direction, and n_{37xy} is a refractive index of the third light extraction layer CPL3 in the vertical thickness direction.

A fourth embodiment of the present disclosure provides an OLED display device. The OLED display device according to the fourth embodiment of the present disclosure is substantially the same as the OLED display devices 1, 2 and 3 according to the first to third embodiments, except that: (n₃ₓ-n_{3y})-(n₁ₓ-n_{1y})≥a sixth preset value, and (n₃ₓ-n_{3y})-(n₂ₓ-n_{2y})≥a seventh preset value, where ranges of both the sixth preset value and the seventh preset value are 0.1˜0.3, n₁ₓ is a sum of refractive indexes of respective layers of the red light-emitting structure 11 in a first direction in the plane where the vertical thickness direction is located, n_{1y} is a sum of refractive indexes of respective layers of the red light-emitting structure 11 in a second direction in the plane where the vertical thickness direction is located, n₂ₓ is a sum of refractive indexes of respective layers of the green light-emitting structure 12 in the first direction in the plane where the vertical thickness direction is located, n_{2y} is a sum of refractive indexes of respective layers of the green light-emitting structure 12 in the second direction in the plane where the vertical thickness direction is located, n₃ₓ is a sum of refractive indexes of respective layers of the blue light-emitting structure 13 in the first direction in the plane where the vertical thickness direction is located, n_{3y} is a sum of refractive indexes of respective layers of the blue light-emitting structure 13 in the second direction in the plane where the vertical thickness direction is located. The first direction is perpendicular to the second direction.

The numerical range in this embodiment includes endpoint values.

It can be seen that a difference between the OLED display device according to this embodiment and the OLED display devices 1, 2 and 3 according to the preceding embodiment is: n₃ₓ≠n_{3y}.

According to the solution in this embodiment, a problem that a color shift in a Y direction is greater than that in an X direction, that is, there tends to be more yellowish in the Y direction than in the X direction, at a large angle of view can be solved.

When there tends to be more yellowish in the X direction than in the Y direction at a large angle of view, it can be controlled that (n_{3y}-n₃ₓ)-(n_{1y}-n₁ₓ)≥a sixth preset value, and (n_{3y}-n₃ₓ)-(n_{2y}-n₂ₓ)≥a seventh preset value.

Based on the above OLED display devices, a fifth embodiment of the present disclosure provides a display panel. In the display panel, OLED display devices are arranged in an array.

In some examples, a planarization layer (not shown) is provided between the substrate 10 and the OLED display devices.

In some examples, a pixel driving circuit is provided between the substrate 10 and the planarization layer. In other words, a light-emitting mode of the red light-emitting structure 11, the green light-emitting structure 12, and the blue light-emitting structure 13 is an Active Matrix (AM) mode.

In some examples, a light-emitting mode of the red light-emitting structure 11, the green light-emitting structure 12, and the blue light-emitting structure 13 is a Passive Matrix (PM) mode. In this case, no pixel driving circuit is provided between the substrate 10 and the planarization layer.

Materials for the first anode 111, the second anode 121, and the third anode 131 may be reflective materials. The reflective materials may include silver (Ag) and its alloys, and aluminum (Al) and its alloys, such as silver (Ag), an alloy of silver and lead (Ag:Pb), an alloy of aluminum and neodymium (Al:Nd), and an alloy of silver, platinum and copper (Ag:Pt:Cu). When silver and its alloys are used as the reflective materials, a layer of ITO, IZO or IGZO can be disposed between the first anode 111, the second anode 121, and the third anode 131 and their respective corresponding OLED light-emitting blocks.

Materials for the first cathode 112, the second cathode 122, and the third cathode 132 may be materials having a partially transparent and partially reflective function (semi-transparent and semi-reflective materials). The first cathode 112, the second cathode 122, and the third cathode 132 may have a single-layer structure, and materials for the single-layer structure may include at least one of magnesium, silver, or aluminum, for example, a mixture of magnesium and silver or a mixture of aluminum and silver. The first cathode 112, the second cathode 122, and the third cathode 132 may have a three-layer structure of a transparent conductive layer, an intermediate layer, and a transparent conductive layer. Materials for the transparent conductive layer may be at least one of ITO, IZO, or IGZO, and materials for the intermediate layer include at least one of magnesium, silver, or aluminum, for example, a mixture of magnesium and silver or a mixture of aluminum and silver. In other words, the red light-emitting structure 11, the green light-emitting structure 12, and the blue light-emitting structure 13 are top emission structures.

In some examples, the red light-emitting structure 11, the green light-emitting structure 12, and the blue light-emitting structure 13 may be bottom emission structures.

Based on the above display panels, an embodiment of the present disclosure provides a display device including any one of the display panels. The display device may be any product or component having a display function, such as electronic paper, a mobile phone, a tablet computer, a television, a notebook computer, a digital photo frame, and a navigator.

It should be pointed out that, in the drawings, sizes of layers and areas may be exaggerated for clarity of illustration. It will also be understood that when an element or layer is referred to as being “on” another element or layer, it can be directly on other element, or an intermediate layer may be present. In addition, it will be understood that when an element or layer is referred to as being “below” another element or layer, it can be directly below other element, or more than one intermediate layer or element may be present. It will also be understood that when a layer or element is referred to as being “between” two layers or elements, it can be the only layer between the two layers or elements, or more than one intermediate layer or element may be present. Similar reference signs indicate similar elements throughout.

In the present disclosure, terms “first” and “second” are used only for descriptive purposes, and cannot be understood as indicating or implying relative importance. Terms “plurality” and “multiple” refer to one, two or more, unless clearly defined otherwise.

Other solutions of the present disclosure will be readily apparent to those skilled in the art after considering the specification and practicing the contents disclosed herein. The present disclosure is intended to cover any variations, uses, or adaptations of the present disclosure, which follow the general principle of the present disclosure and include common knowledge or conventional technical means in the art that are not disclosed in the present disclosure. The specification and embodiments are to be regarded as illustrative only. The true scope and spirit of the present disclosure are pointed out by the following claims.

It is to be understood that the present disclosure is not limited to the precise structures that have described and shown in the drawings, and various modifications and changes can be made without departing from the scope thereof. The scope of the present disclosure is to be limited only by the appended claims.

1. An Organic Light-Emitting Diode (OLED) display device, comprising: a red light-emitting structure, a green light-emitting structure, and a blue light-emitting structure, wherein (n_{3z}-n_{3xy})-(n_{1z}-n_{1xy})≥a first preset value, and (n_{3z}-n_{3xy})-(n_{2z}-n_{2xy})≥a second preset value, wherein ranges of both the first preset value and the second preset value are 0.1˜0.3; n_{1z} is a sum of refractive indexes of respective layers of the red light-emitting structure in a thickness direction; n_{1xy} is a sum of refractive indexes of the respective layers of the red light-emitting structure in a vertical thickness direction; n_{2z} is a sum of refractive indexes of respective layers of the green light-emitting structure in the thickness direction; n_{2xy} is a sum of refractive indexes of the respective layers of the green light-emitting structure in the vertical thickness direction; n_{3z} is a sum of refractive indexes of respective layers of the blue light-emitting structure in the thickness direction; and n_{3xy} is a sum of refractive indexes of the respective layers of the blue light-emitting structure in the vertical thickness direction.

2. The OLED display device according to claim 1, wherein the respective layers of the red light-emitting structure include a first anode, a first cathode, and a red OLED light-emitting block located between the first anode and the first cathode; the respective layers of the green light-emitting structure include a second anode, a second cathode, and a green OLED light-emitting block located between the second anode and the second cathode; the respective layers of the blue light-emitting structure include a third anode, a third cathode, and a blue OLED light-emitting block located between the third anode and the third cathode.

3. The OLED display device according to claim 2, wherein the first anode, the second anode, and the third anode are located in a same layer and any two among them are disconnected to each other, and the first cathode, the second cathode, and the third cathode are located in a same layer and are connected together;
(n_{31z}-n_{31xy})-(n_{11z}-n_{11xy})≥the first preset value, and (n_{31z}-n_{31xy})-(n_{21z}-n_{21xy})≥the second preset value, wherein n_{11z} is a refractive index of the first anode in the thickness direction; n_{11xy} is a refractive index of the first anode in the vertical thickness direction; n_{21z} is a refractive index of the second anode in the thickness direction; n_{21xy} is a refractive index of the second anode in the vertical thickness direction; n_{31z} is a refractive index of the third anode in the thickness direction; n_{31xy} is a refractive index of the third anode in the vertical thickness direction; and/or
(n_{32z}-n_{32xy})-(n_{12z}-n_{12xy})≥the first preset value, and (n_{32z}-n_{32xy})-(n_{22z}-n_{22xy})≥the second preset value, wherein n_{12z} is a refractive index of the red OLED light-emitting block in the thickness direction; n_{12xy} is a refractive index of the red OLED light-emitting block in the vertical thickness direction; n_{22z} is a refractive index of the green OLED light-emitting block in the thickness direction; n_{22xy} is a refractive index of the green OLED light-emitting block in the vertical thickness direction; n_{32z} is a refractive index of the blue OLED light-emitting block in the thickness direction; n_{32xy} is a refractive index of the blue OLED light-emitting block in the vertical thickness direction.

4. The OLED display device according to claim 2, wherein the respective layers of the red light-emitting structure further include at least one of a first hole transport layer, a first electron barrier layer, a first hole barrier layer, or a first electron transport layer, wherein the first hole transport layer and the first electron barrier layer are located between the first anode and the red OLED light-emitting block, the first hole transport layer is close to the first anode, the first electron barrier layer is far away from the first anode, the first hole barrier layer and the first electron transport layer are located between the first cathode and the red OLED light-emitting block, the first hole barrier layer is far away from the first cathode, and the first electron transport layer is close to the first cathode;
the respective layers of the green light-emitting structure further include at least one of a second hole transport layer, a second electron barrier layer, a second hole barrier layer, or a second electron transport layer, wherein the second hole transport layer and the second electron barrier layer are located between the second anode and the green OLED light-emitting block, the second hole transport layer is close to the second anode, the second electron barrier layer is far away from the second anode, the second hole barrier layer and the second electron transport layer are located between the second cathode and the green OLED light-emitting block, the second hole barrier layer is far away from the second cathode, and the second electron transport layer is close to the second cathode;
the respective layers of the blue light-emitting structure further include at least one of a third hole transport layer, a third electron barrier layer, a third hole barrier layer, or a third electron transport layer, wherein the third hole transport layer and the third electron barrier layer are located between the third anode and the blue OLED light-emitting block, the third hole transport layer is close to the third anode, the third electron barrier layer is far away from the third anode, the third hole barrier layer and the third electron transport layer are located between the third cathode and the blue OLED light-emitting block, the third hole barrier layer is far away from the third cathode, and the third electron transport layer is close to the third cathode.

5. The OLED display device according to claim 4, wherein the first hole transport layer, the second hole transport layer, and the third hole transport layer are located in a same layer and any two among them are disconnected to each other; (n_{33z}-n_{33xy})-(n_{13z}-n_{13xy})≥the first preset value, and (n_{33z}-n_{33xy})-(n_{23z}-n_{23xy})≥the second preset value, wherein n_{13z} is a refractive index of the first hole transport layer in the thickness direction, n_{13xy} is a refractive index of the first hole transport layer in the vertical thickness direction, n_{23z} is a refractive index of the second hole transport layer in the thickness direction, n_{23xy} is a refractive index of the second hole transport layer in the vertical thickness direction, n_{33z} is a refractive index of the third hole transport layer in the thickness direction, and n_{33xy} is a refractive index of the third hole transport layer in the vertical thickness direction; and/or
the first electron barrier layer, the second electron barrier layer, and the third electron barrier layer are located in a same layer and any two among them are disconnected to each other; (n_{34z}-n_{34xy})-(n_{14z}-n_{14xy})≥the first preset value, and (n_{34z}-n_{34xy})-(n_{24z}-n_{24xy})≥the second preset value, wherein n_{14z} is a refractive index of the first electron barrier layer in the thickness direction, n_{14xy} is a refractive index of the first electron barrier layer in the vertical thickness direction, n_{24z} is a refractive index of the second electron barrier layer in the thickness direction, n_{24xy} is a refractive index of the second electron barrier layer in the vertical thickness direction, n_{34z} is a refractive index of the third electron barrier layer in the thickness direction, and n_{34xy} is a refractive index of the third electron barrier layer in the vertical thickness direction; and/or
the first hole barrier layer, the second hole barrier layer, and the third hole barrier layer are located in a same layer and any two among them are disconnected to each other; (n_{35z}-n_{35xy})-(n_{15z}-n_{15xy})≥the first preset value, and (n_{35z}-n_{35xy})-(n_{25z}-n_{25xy})≥the second preset value, wherein n_{15z} is a refractive index of the first hole barrier layer in the thickness direction, n_{15xy} is a refractive index of the first hole barrier layer in the vertical thickness direction, n_{25z} is a refractive index of the second hole barrier layer in the thickness direction, n_{25xy} is a refractive index of the second hole barrier layer in the vertical thickness direction, n_{35z} is a refractive index of the third hole barrier layer in the thickness direction, and n_{35xy} is a refractive index of the third hole barrier layer in the vertical thickness direction; and/or
the first electron transport layer, the second electron transport layer, and the third electron transport layer are located in a same layer and any two among them are disconnected to each other; (n_{36z}-n_{36xy})-(n_{16z}-n_{16xy})≥the first preset value, and (n_{36z}-n_{36xy})-(n_{26z}-n_{26xy})≥the second preset value, wherein n_{16z} is a refractive index of the first electron transport layer in the thickness direction, n_{16xy} is a refractive index of the first electron transport layer in the vertical thickness direction, n_{26z} is a refractive index of the second electron transport layer in the thickness direction, n_{26xy} is a refractive index of the second electron transport layer in the vertical thickness direction, n_{36z} is a refractive index of the third electron transport layer in the thickness direction, and n_{36xy} is a refractive index of the third electron transport layer in the vertical thickness direction.

6. The OLED display device according to claim 2, wherein the respective layers of the red light-emitting structure further include a first light extraction layer, wherein the first light extraction layer is located on a side of the first cathode away from the red OLED light-emitting block; the respective layers of the green light-emitting structure further include a second light extraction layer, wherein the second light extraction layer is located on a side of the second cathode away from the green OLED light-emitting block; the respective layers of the blue light-emitting structure further include a third light extraction layer, wherein the third light extraction layer is located on a side of the third cathode away from the blue OLED light-emitting block.

7. The OLED display device according to claim 6, wherein the first light extraction layer, the second light extraction layer, and the third light extraction layer are located in a same layer and any two among them are disconnected to each other; (n_{37z}-n_{37xy})-(n_{17z}-n_{17xy})≥the first preset value, and (n_{37z}-n_{37xy})-(n_{27z}-n_{27xy})≥the second preset value, wherein n_{17z} is a refractive index of the first light extraction layer in the thickness direction, n_{17xy} is a refractive index of the first light extraction layer in the vertical thickness direction, n_{27z} is a refractive index of the second light extraction layer in the thickness direction, n_{27xy} is a refractive index of the second light extraction layer in the vertical thickness direction, n_{37z} is a refractive index of the third light extraction layer in the thickness direction, and n_{37xy} is a refractive index of the third light extraction layer in the vertical thickness direction.

8. The OLED display device according to claim 1, wherein n_{1z}=n_{1xy}, and/or n_{2z}=n_{2xy}.

9. The OLED display device according to claim 1, wherein n_{3z}-n_{3xy}≥a third preset value, and n_{1z}-n_{1xy}≤a fourth preset value, wherein the third preset value−the fourth preset value=the first preset value; n_{2z}-n_{2xy}≤a fifth preset value, wherein the third preset value−the fifth preset value=the second preset value.

10. The OLED display device according to claim 1, wherein (n₃ₓ-n_{3y})-(n₁ₓ-n_{1y})≥a sixth preset value, and (n₃ₓ-n_{3y})-(n₂ₓ-n_{2y})≥a seventh preset value, wherein ranges of both the sixth preset value and the seventh preset value are 0.1˜0.3, n₁ₓ is a sum of refractive indexes of the respective layers of the red light-emitting structure in a first direction in a plane where the vertical thickness direction is located, n_{1y} is a sum of refractive indexes of the respective layers of the red light-emitting structure in a second direction in the plane where the vertical thickness direction is located, n₂ₓ is a sum of refractive indexes of the respective layers of the green light-emitting structure in the first direction in the plane where the vertical thickness direction is located, n_{2y} is a sum of refractive indexes of the respective layers of the green light-emitting structure in the second direction in the plane where the vertical thickness direction is located, n₃ₓ is a sum of refractive indexes of the respective layers of the blue light-emitting structure in the first direction in the plane where the vertical thickness direction is located, n_{3y} is a sum of refractive indexes of the respective layers of the blue light-emitting structure in the second direction in the plane where the vertical thickness direction is located, wherein the first direction is perpendicular to the second direction.

11. The OLED display device according to claim 1, wherein (n_{3y}-n₃ₓ)-(n_{1y}-n₁ₓ)≥a sixth preset value, and (n_{3y}-n₃ₓ)-(n_{2y}-n₂ₓ)≥a seventh preset value, wherein ranges of both the sixth preset value and the seventh preset value are 0.1˜0.3, n₁ₓ is a sum of refractive indexes of the respective layers of the red light-emitting structure in a first direction in a plane where the vertical thickness direction is located, n_{1y} is a sum of refractive indexes of the respective layers of the red light-emitting structure in a second direction in the plane where the vertical thickness direction is located, n₂ₓ is a sum of refractive indexes of the respective layers of the green light-emitting structure in the first direction in the plane where the vertical thickness direction is located, n_{2y} is a sum of refractive indexes of the respective layers of the green light-emitting structure in the second direction in the plane where the vertical thickness direction is located, n₃ₓ is a sum of refractive indexes of the respective layers of the blue light-emitting structure in the first direction in the plane where the vertical thickness direction is located, n_{3y} is a sum of refractive indexes of the respective layers of the blue light-emitting structure in the second direction in the plane where the vertical thickness direction is located, wherein the first direction is perpendicular to the second direction.

12. A display panel, comprising: Organic Light-Emitting Diode (OLED) display devices, wherein the OLED display devices are arranged in an array and an OLED display device comprises:
a red light-emitting structure, a green light-emitting structure, and a blue light-emitting structure, wherein (n_{3z}-n_{3xy})-(n_{1z}-n_{1xy})≥a first preset value, and (n_{3z}-n_{3xy})-(n_{2z}-n_{2xy})≥a second preset value, wherein ranges of both the first preset value and the second preset value are 0.1˜0.3; n_{1z} is a sum of refractive indexes of respective layers of the red light-emitting structure in a thickness direction; n_{1xy} is a sum of refractive indexes of the respective layers of the red light-emitting structure in a vertical thickness direction; n_{2z} is a sum of refractive indexes of respective layers of the green light-emitting structure in the thickness direction; n_{2xy} is a sum of refractive indexes of the respective layers of the green light-emitting structure in the vertical thickness direction; n_{3z} is a sum of refractive indexes of respective layers of the blue light-emitting structure in the thickness direction; and n_{3xy} is a sum of refractive indexes of the respective layers of the blue light-emitting structure in the vertical thickness direction.

13. The display panel according to claim 12, wherein the OLED display devices have a bottom or top emission structure.

14. A display device, comprising: a display panel according to claim 12.

15. The display panel according to claim 12, wherein the respective layers of the red light-emitting structure include a first anode, a first cathode, and a red OLED light-emitting block located between the first anode and the first cathode; the respective layers of the green light-emitting structure include a second anode, a second cathode, and a green OLED light-emitting block located between the second anode and the second cathode; the respective layers of the blue light-emitting structure include a third anode, a third cathode, and a blue OLED light-emitting block located between the third anode and the third cathode.

16. The display panel according to claim 15, wherein the first anode, the second anode, and the third anode are located in a same layer and any two among them are disconnected to each other, and the first cathode, the second cathode, and the third cathode are located in a same layer and are connected together;
(n_{31z}-n_{31xy})-(n_{11z}-n_{11xy})≥the first preset value, and (n_{31z}-n_{31xy})-(n_{21z}-n_{21xy})≥the second preset value, wherein n_{11z} is a refractive index of the first anode in the thickness direction; n_{11xy} is a refractive index of the first anode in the vertical thickness direction; n_{21z} is a refractive index of the second anode in the thickness direction; n_{21xy} is a refractive index of the second anode in the vertical thickness direction; n_{31z} is a refractive index of the third anode in the thickness direction; n_{31xy} is a refractive index of the third anode in the vertical thickness direction; and/or
(n_{32z}-n_{32xy})-(n_{12z}-n_{12xy})≥the first preset value, and (n_{32z}-n_{32xy})-(n_{22z}-n_{22xy})≥the second preset value, wherein n_{12z} is a refractive index of the red OLED light-emitting block in the thickness direction; n_{12xy} is a refractive index of the red OLED light-emitting block in the vertical thickness direction; n_{22z} is a refractive index of the green OLED light-emitting block in the thickness direction; n_{22xy} is a refractive index of the green OLED light-emitting block in the vertical thickness direction; n_{32z} is a refractive index of the blue OLED light-emitting block in the thickness direction; n_{32xy} is a refractive index of the blue OLED light-emitting block in the vertical thickness direction.

17. The display panel according to claim 15, wherein the respective layers of the red light-emitting structure further include at least one of a first hole transport layer, a first electron barrier layer, a first hole barrier layer, or a first electron transport layer, wherein the first hole transport layer and the first electron barrier layer are located between the first anode and the red OLED light-emitting block, the first hole transport layer is close to the first anode, the first electron barrier layer is far away from the first anode, the first hole barrier layer and the first electron transport layer are located between the first cathode and the red OLED light-emitting block, the first hole barrier layer is far away from the first cathode, and the first electron transport layer is close to the first cathode;
the respective layers of the green light-emitting structure further include at least one of a second hole transport layer, a second electron barrier layer, a second hole barrier layer, or a second electron transport layer, wherein the second hole transport layer and the second electron barrier layer are located between the second anode and the green OLED light-emitting block, the second hole transport layer is close to the second anode, the second electron barrier layer is far away from the second anode, the second hole barrier layer and the second electron transport layer are located between the second cathode and the green OLED light-emitting block, the second hole barrier layer is far away from the second cathode, and the second electron transport layer is close to the second cathode;
the respective layers of the blue light-emitting structure further include at least one of a third hole transport layer, a third electron barrier layer, a third hole barrier layer, or a third electron transport layer, wherein the third hole transport layer and the third electron barrier layer are located between the third anode and the blue OLED light-emitting block, the third hole transport layer is close to the third anode, the third electron barrier layer is far away from the third anode, the third hole barrier layer and the third electron transport layer are located between the third cathode and the blue OLED light-emitting block, the third hole barrier layer is far away from the third cathode, and the third electron transport layer is close to the third cathode.

18. The display panel according to claim 17, wherein the first hole transport layer, the second hole transport layer, and the third hole transport layer are located in a same layer and any two among them are disconnected to each other; (n_{33z}-n_{33xy})-(n_{13z}-n_{13xy})≥the first preset value, and (n_{33z}-n_{33xy})-(n_{23z}-n_{23xy})≥the second preset value, wherein n_{13z} is a refractive index of the first hole transport layer in the thickness direction, n_{13xy} is a refractive index of the first hole transport layer in the vertical thickness direction, n_{23z} is a refractive index of the second hole transport layer in the thickness direction, n_{23xy} is a refractive index of the second hole transport layer in the vertical thickness direction, n_{33z} is a refractive index of the third hole transport layer in the thickness direction, and n_{33xy} is a refractive index of the third hole transport layer in the vertical thickness direction; and/or
the first electron barrier layer, the second electron barrier layer, and the third electron barrier layer are located in a same layer and any two among them are disconnected to each other; (n_{34z}-n_{34xy})-(n_{14z}-n_{14xy})≥the first preset value, and (n_{34z}-n_{34xy})-(n_{24z}-n_{24xy})≥the second preset value, wherein n_{14z} is a refractive index of the first electron barrier layer in the thickness direction, n_{14xy} is a refractive index of the first electron barrier layer in the vertical thickness direction, n_{24z} is a refractive index of the second electron barrier layer in the thickness direction, n_{24xy} is a refractive index of the second electron barrier layer in the vertical thickness direction, n_{34z} is a refractive index of the third electron barrier layer in the thickness direction, and n_{34xy} is a refractive index of the third electron barrier layer in the vertical thickness direction; and/or
the first hole barrier layer, the second hole barrier layer, and the third hole barrier layer are located in a same layer and any two among them are disconnected to each other; (n_{35z}-n_{35xy})-(n_{15z}-n_{15xy})≥the first preset value, and (n_{35z}-n_{35xy})-(n_{25z}-n_{25xy})≥the second preset value, wherein n_{15z} is a refractive index of the first hole barrier layer in the thickness direction, n_{15xy} is a refractive index of the first hole barrier layer in the vertical thickness direction, n_{25z} is a refractive index of the second hole barrier layer in the thickness direction, n_{25xy} is a refractive index of the second hole barrier layer in the vertical thickness direction, n_{35z} is a refractive index of the third hole barrier layer in the thickness direction, and n_{35xy} is a refractive index of the third hole barrier layer in the vertical thickness direction; and/or
the first electron transport layer, the second electron transport layer, and the third electron transport layer are located in a same layer and any two among them are disconnected to each other; (n_{36z}-n_{36xy})-(n_{16z}-n_{16xy})≥the first preset value, and (n_{36z}-n_{36xy})-(n_{26z}-n_{26xy})≥the second preset value, wherein n_{16z} is a refractive index of the first electron transport layer in the thickness direction, n_{16xy} is a refractive index of the first electron transport layer in the vertical thickness direction, n_{26z} is a refractive index of the second electron transport layer in the thickness direction, n_{26xy} is a refractive index of the second electron transport layer in the vertical thickness direction, n_{36z} is a refractive index of the third electron transport layer in the thickness direction, and n_{36xy} is a refractive index of the third electron transport layer in the vertical thickness direction.

19. The display panel according to claim 15, wherein the respective layers of the red light-emitting structure further include a first light extraction layer, wherein the first light extraction layer is located on a side of the first cathode away from the red OLED light-emitting block; the respective layers of the green light-emitting structure further include a second light extraction layer, wherein the second light extraction layer is located on a side of the second cathode away from the green OLED light-emitting block; the respective layers of the blue light-emitting structure further include a third light extraction layer, wherein the third light extraction layer is located on a side of the third cathode away from the blue OLED light-emitting block.

20. The display panel according to claim 19, wherein the first light extraction layer, the second light extraction layer, and the third light extraction layer are located in a same layer and any two among them are disconnected to each other; (n_{37z}-n_{37xy})-(n_{17z}-n_{17xy})≥the first preset value, and (n_{37z}-n_{37xy})-(n_{27z}-n_{27xy})≥the second preset value, wherein n_{17z} is a refractive index of the first light extraction layer in the thickness direction, n_{17xy} is a refractive index of the first light extraction layer in the vertical thickness direction, n_{27z} is a refractive index of the second light extraction layer in the thickness direction, n_{27xy} is a refractive index of the second light extraction layer in the vertical thickness direction, n_{37z} is a refractive index of the third light extraction layer in the thickness direction, and n_{37xy} is a refractive index of the third light extraction layer in the vertical thickness direction.
